(19) United States
(12) Patent Application Publication
(10) Pub. No.: US 2024/0321899 A1
(43) Pub. Date: Sep. 26, 2024

(54) DISPLAY PANEL AND DISPLAY DEVICE

(71) Applicant: Shanghai AVIC OPTO Electronics Co., Ltd., Shanghai (CN)

(72) Inventors: Bo TANG, Shanghai (CN); Hao GUO, Shanghai (CN)

(21) Appl. No.: 18/221,578

(22) Filed: Jul. 13, 2023

(30) Foreign Application Priority Data
Mar. 24, 2023 (CN) 202310301378.4

(51) Int. Cl. H01L 27/12; G09G 3/36

(52) U.S. Cl. CPC H01L 27/124; G09G 3/3674; G09G 2300/0413; G09G 2310/0286

(57) ABSTRACT

A display panel and a display device are provided. The display panel includes a display area and a non-display area surrounding the display area. The display panel includes a substrate, and scan lines and data lines disposed over the substrate. The data lines are disposed in the display area. The data lines extend along a first direction and are arranged along a second direction. The scan lines extend along the second direction and are arranged along the first direction. The display panel also includes at least one dummy signal line disposed in the non-display area. The dummy signal line is parallel to the data lines. The dummy signal line includes a first dummy signal line closest to an outer edge of the non-display area. Along the second direction, one end of at least one scan line is located between the first dummy signal line and the data lines.

### CROSS-REFERENCE TO RELATED APPLICATION

This application claims priority of Chinese Patent Application No. 202310301378.4, filed on Mar. 24, 2023, the entire content of which is hereby incorporated by reference.

### FIELD OF THE DISCLOSURE

The present disclosure generally relates to the field of display technology and, more particularly, relates to a display panel and a display device.

### BACKGROUND

From an era of cathode ray tube (CRT) display to an era of liquid crystal display (LCD), and now to an era of organic light-emitting diode (OLED) display and an era of light-emitting diode (LED) display, display industry has experienced decades of development and is developing quickly. Display industry is closely related to our life. From conventional mobile phones, tablets, TVs, computers, to current smart wearable devices, virtual reality devices, vehicle display devices and other electronic devices, display technology is indispensable.

A large quantity of signal lines and electronic components are disposed in the display panel, and static electricity in a display panel is likely to affect display effects. As such, how to reduce impacts of static electricity on display panels has become one of the technical problems to be solved urgently at this stage.

### SUMMARY

One aspect of the present disclosure includes a display panel. The display panel includes a display area and a non-display area surrounding the display area. The display panel includes a substrate, and a plurality of scan lines and a plurality of data lines disposed over the substrate. The plurality of data lines is disposed in the display area, the plurality of data lines extends along a first direction and is arranged along a second direction, and the plurality of scan lines extends along the second direction and is arranged along the first direction. The first direction and the second direction intersect. The display panel also includes at least one dummy signal line disposed in the non-display area. The at least one dummy signal line is parallel to the plurality of data lines, the at least one dummy signal line includes a first dummy signal line that is closest to an outer edge of the non-display area among the at least one dummy signal line, and along the second direction, one end of at least one scan line of the plurality of scan lines is located between the first dummy signal line and the plurality of data lines.

Another aspect of the present disclosure includes a display device. The display device includes a display panel. The display panel includes a display area and a non-display area surrounding the display area. The display panel includes a substrate, and a plurality of scan lines and a plurality of data lines disposed over the substrate. The plurality of data lines is disposed in the display area, the plurality of data lines extends along a first direction and is arranged along a second direction, and the plurality of scan lines extends along the second direction and is arranged along the first direction. The first direction and the second direction intersect. The display panel also includes at least one dummy signal line disposed in the non-display area. The at least one dummy signal line is parallel to the plurality of data lines, the at least one dummy signal line includes a first dummy signal line that is closest to an outer edge of the non-display area among the at least one dummy signal line, and along the second direction, one end of at least one scan line of the plurality of scan lines is located between the first dummy signal line and the plurality of data lines.

Other aspects of the present disclosure may be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a diagram of a relative position relationship between scan lines and dummy signal lines in a non-display area of a display panel in existing technology;

FIG. 2 illustrates a BB cross-sectional view of the signal line in FIG. 1;

FIG. 3 illustrates a top view of a display panel consistent with the disclosed embodiments of the present disclosure;

FIG. 4 illustrates an enlarged schematic diagram of area Q of the display panel shown in FIG. 3, consistent with the disclosed embodiments of the present disclosure;

FIG. 5 illustrates a CC cross-sectional view of FIG. 4, consistent with the disclosed embodiments of the present disclosure;

FIG. 6 illustrates another enlarged schematic diagram of area Q of the display panel shown in FIG. 3, consistent with the disclosed embodiments of the present disclosure;

FIG. 7 illustrates an enlarged schematic diagram of a part of scan lines in a non-display area and a display area of the display panel shown in FIG. 3, consistent with the disclosed embodiments of the present disclosure;

FIG. 8 illustrates another top view of a display panel consistent with the disclosed embodiments of the present disclosure;

FIG. 9 illustrates a DD cross-sectional view of the display panel shown in FIG. 8, consistent with the disclosed embodiments of the present disclosure;

FIG. 10 illustrates an EE cross-sectional view of the display panel shown in FIG. 8, consistent with the disclosed embodiments of the present disclosure;

FIG. 11 illustrates a top view of a conductive metal portion consistent with the disclosed embodiments of the present disclosure;

FIG. 12 illustrates a layer relationship diagram of a conductive metal portion, a first dummy signal line and a scan line in a first non-display area, consistent with the disclosed embodiments of the present disclosure;

FIG. 13 illustrates another top view of a display panel consistent with the disclosed embodiments of the present disclosure;

FIG. 14 illustrates a diagram of a relative position relationship among a first conductive metal portion, a first dummy signal line, a data line, and a scan line, consistent with the disclosed embodiments of the present disclosure;

FIG. 15 illustrates an FF direction cross-sectional view of FIG. 14, consistent with the disclosed embodiments of the present disclosure;

FIG. 16 illustrates another top view of a display panel consistent with the disclosed embodiments of the present disclosure;

FIG. 17 illustrates a partial enlarged view of a fourth non-display area and a part of a display area adjacent to the fourth non-display area in a display panel consistent with the disclosed embodiments of the present disclosure;

FIG. 18 illustrates another partial enlarged view of a fourth non-display area and a part of a display area adjacent to the fourth non-display area in a display panel consistent with the disclosed embodiments of the present disclosure;

FIG. 19 illustrates another top view of a display panel consistent with the disclosed embodiments of the present disclosure;

FIG. 20 illustrates another partial enlarged view of a fourth non-display area and a part of a display area adjacent to the fourth non-display area in a display panel consistent with the disclosed embodiments of the present disclosure;

FIG. 21 illustrates another partial enlarged view of a fourth non-display area and a part of a display area adjacent to the fourth non-display area in a display panel consistent with the disclosed embodiments of the present disclosure;

FIG. 22 illustrates a schematic connection diagram of a scan line and a sub-pixel in a display panel consistent with the disclosed embodiments of the present disclosure;

FIG. 23 illustrates another schematic structural diagram of a display panel consistent with the disclosed embodiments of the present disclosure;

FIG. 24 illustrates another schematic structural diagram of a display panel consistent with the disclosed embodiments of the present disclosure;

FIG. 25 illustrates another schematic structural diagram of a display panel consistent with the disclosed embodiments of the present disclosure;

FIG. 26 illustrates an FF direction cross-sectional view of FIG. 14, consistent with the disclosed embodiments of the present disclosure; and

FIG. 27 illustrates a schematic structural diagram of a display device consistent with the disclosed embodiments of the present disclosure.

### DETAILED DESCRIPTION

To make the objectives, technical solutions and advantages of the present disclosure clearer and more explicit, the present disclosure is described in further detail with accompanying drawings and embodiments. It should be understood that the specific exemplary embodiments described herein are only for explaining the present disclosure and are not intended to limit the present disclosure.

Technologies, methods, and equipment known to those of ordinary skill in relevant fields may not be discussed in detail, but where appropriate, these technologies, methods, and equipment should be regarded as part of the specification.

In the present disclosure, any specific values should be construed as examples only, and not as limitations. Different embodiments may have different values.

Reference will now be made in detail to embodiments of the present disclosure, which are illustrated in the accompanying drawings. Similar labels and letters designate similar items in the drawings. Once an item is defined in one drawing, the item may not be defined and discussed in subsequent drawings.

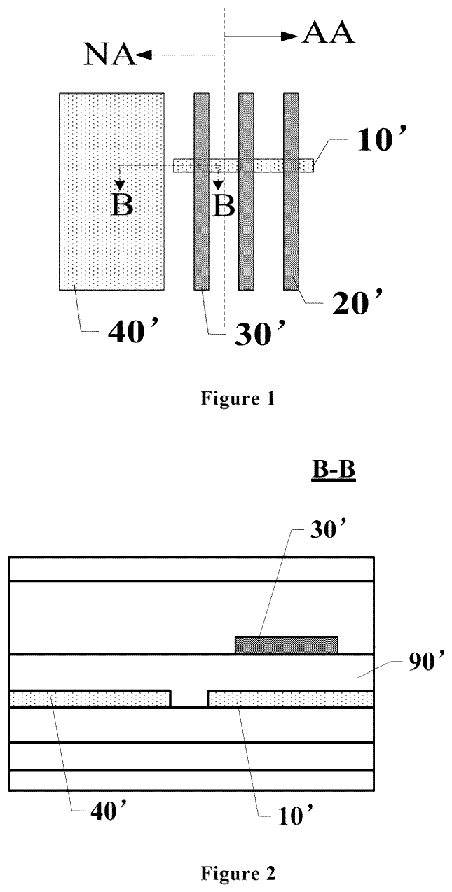

FIG. 1 illustrates a diagram of a relative position relationship between a scan line 10′, a dummy signal line 30′, and a data line 20′ in a non-display area of a display panel in existing technology. FIG. 2 illustrates a BB cross-sectional view of the signal line in FIG. 1. In existing technology, the non-display area NA of the display panel is disposed with the dummy signal lines 30′ and metal lines 40′. The scan line 10′ extends into the non-display area NA. The scan line 10′ overlaps with the dummy signal line 30′ in a thickness direction. A phenomenon of tip discharge may occur between the end of the scan line 10′ and the metal line 40′. The static electricity caused by the tip discharge may break down an insulating layer 90′ between the scan line 10′ and the dummy signal line 30′, causing the scan line 10′ to be electrically connected to the dummy signal line 30′. In this case, signals on the scan line 10′ may become abnormal, resulting in abnormal display of sub-pixels connected to the scan line 10′, and abnormal display of the entire display panel. For example, when displaying a white image, the sub-pixels connected to the scan lines may be in a black state, and dark lines may appear on the display panel.

To address the above issues, the present disclosure provides a display panel. The display panel includes a display area and a non-display area surrounding the display area. The display panel includes a substrate, and a plurality of scan lines and a plurality of data lines disposed over the substrate. The data lines are disposed in the display area. The data lines extend along a first direction and are arranged along a second direction. The scan lines extend along the second direction and are arranged along the first direction. The first direction intersects with the second direction. At least one dummy signal line is disposed in the non-display area. The dummy signal line is parallel to the data lines. The dummy signal line includes a first dummy signal line, among the at least one dummy signal line, that is closest to an outer edge of the non-display area. Along the second direction, one end of at least one scan line is located between the first dummy signal line and the data line. By arranging the end of the scan line away from the first dummy signal line, an overlap of the end of the scan line and the first dummy signal line in the thickness direction may be avoided. As such, abnormal display caused by the electrical connection between the end of the scan line and the first dummy signal line due to electrostatic breakdown may be avoided, and the overall display effect may be improved.

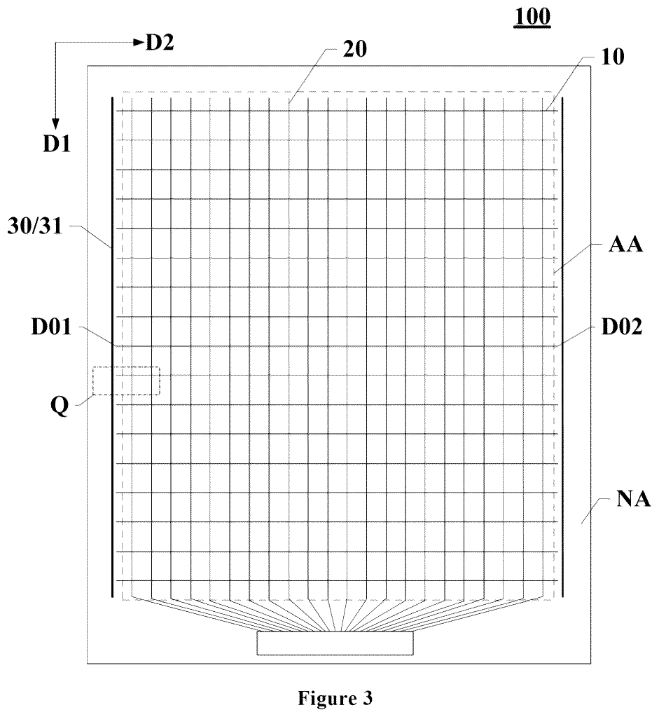

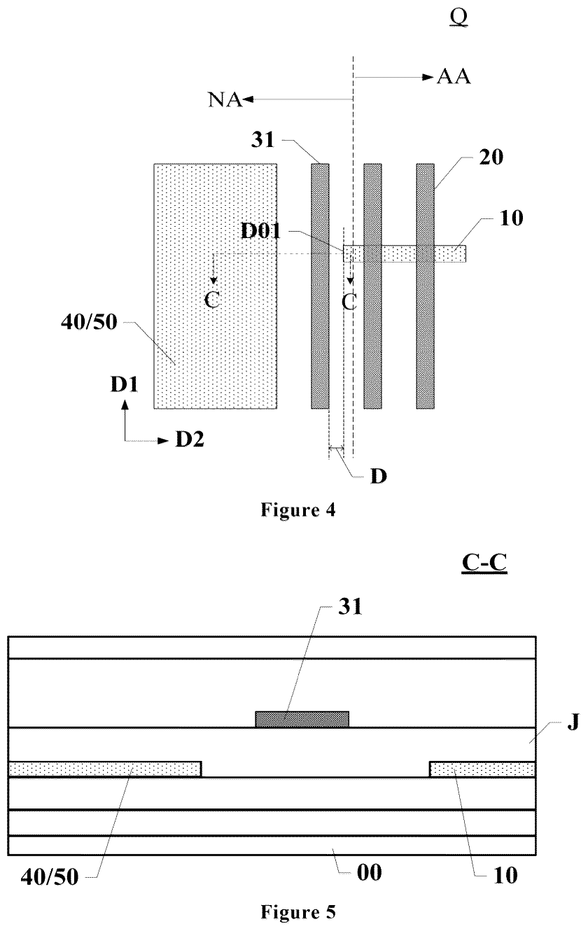

FIG. 3 illustrates a top view of a display panel consistent with the disclosed embodiments of the present disclosure. FIG. 4 illustrates an enlarged schematic diagram of area Q of the display panel shown in FIG. 3. FIG. 5 illustrates a CC cross-sectional view of FIG. 4. Referring to FIGS. 3-5, the present disclosure provides a display panel 100. The display panel 100 includes a display area AA and a non-display area NA surrounding the display area AA.

The display panel 100 includes a substrate 00, and a plurality of scan lines 10 and a plurality of data lines 20 disposed over the substrate 00. The data lines 20 are disposed in the display area AA. The data lines 20 extend along a first direction D1 and are arranged along a second direction D2. The scan lines 10 extend along the second direction D2 and are arranged along the first direction D1. The first direction D1 and the second direction D2 intersect. At least one dummy signal line 30 is disposed in the non-display area NA. The dummy signal line 30 is parallel to the data line 20. The dummy signal line 30 includes a first dummy signal line 31 that is closest to an outer edge of the non-display area NA. Along the second direction D2, one end of at least one scan line 10 is located between the first dummy signal line 31 and the data line 20.

It should be noted that FIG. 3 only uses a display panel with a rectangular structure as an example for illustration, and does not limit the shape of the display panel. In some other embodiments of the present disclosure, the shape of the display panel may be in other shapes, such as a rounded rectangle, a circle or other feasible shapes. Optionally, in a display panel provided by the present disclosure, the scan lines 10 extend along the second direction D2, and the data lines 20 extend along the first direction D1.

It should also be noted that the scan line 10 and the data line 20 in FIG. 3 are each illustrated by taking a straight line structure as an example. Actual line shapes of the scan line 10 and the data line 20 are not limited, provided that an overall extending direction of the scan lines 10 is the second direction D2 and an overall extending direction of the data lines 20 is the first direction D1. On this basis, the scan lines 10 and the data lines 20 may not be strictly linear structures. FIG. 3 only illustrates a part of the scan lines 10 and data lines 20 in the display panel, and does not represent actual quantities of the scan lines 10 and the data lines 20 actually included in the display panel. The layer structure shown in FIG. 5 only shows a relative positional relationship between the first dummy signal line 31 and the scan line 10, and does not limit an actual layer structure and an actual quantity of layers of the display panel.

Specifically, the display panel includes the scan lines 10 and the data lines 20 arranged crosswise. The data lines 20 extend along the first direction D1, and the scan lines 10 extend along the second direction D2. The data lines 20 are disposed in the display area AA and are configured to provide data signals to sub-pixels in the display panel. The scan lines 10 are configured to provide scan signals to the sub-pixels. The dummy signal line 30 is disposed in the non-display area NA. The dummy signal line 30 is parallel to the data line 20. The first dummy signal line 31 refers to the dummy signal line 30 farthest from the data line 20. When a plurality of dummy signal lines 30 is disposed in the non-display area NA on a same side of the display area AA, the first dummy signal line 31 may be regarded as the dummy signal line 30 farthest from the outer edge of the display area AA.

Since the extension direction of the scan line 10 crosses the data line 20, the end of the scan line 10 may extend to the non-display area NA. When the non-display area NA is disposed with a signal line 40 (for example, a metal wiring with a large area, such as a bulk metal structure with a line width much larger than a line width of the scan line 10), a tip discharge phenomenon may occur between the end of the scan line 10 and the signal line 40. When the end of the scan line 10 overlap with the first dummy signal lines 31 in the thickness direction of the display panel, the static electricity may break down an insulating layer J between the end of the scan line 10 and the first dummy signal line 31, resulting in the electrical connection between the scan line 10 and the first dummy signal line 31. As a result, normal display of the sub-pixels connected to the scan line 10 may be affected, and for example, dark lines may appear.

In one embodiment, along the second direction D2, the end of the scan line 10 is disposed between the first dummy signal line 31 and the data line 20. Accordingly, the overlap between the end of the scan line 10 and the first dummy signal lines 31 along the thickness direction of the display panel may be avoided. On the one hand, a distance along the second direction D2 between the end of the scan line 10 and the edge of the non-display area NA may be increased. As such, the distance between the end of the scan line 10 and the signal line 40 in the non-display area NA may be increased, and possibility of tip discharge occurring between the end of the scan line 10 and the signal line 40 may be reduced. On the other hand, the end of the scan line 10 does not overlap with the first dummy signal lines 31 in the thickness direction of the display panel. As such, the electric connection between the end of the scan line 10 and the first dummy signal line 31 caused by tip discharge may be avoided. As a result, abnormal display caused by the electrical connection between the scan line 10 and the first dummy signal line 31 may be avoided. Accordingly, the impact of static electricity on the display effect may be avoided, and the overall display effect of the display panel may be improved.

Still referring to FIGS. 3 and 4, in one embodiment, the scan line 10 includes a first terminal D01 and a second terminal D02 opposite to each other along the second direction D2. The first terminal D01 is located between the first dummy signal line 31 and the data line 20. A distance between the first terminal D01 and the first dummy signal line 31 is D, with D≥30 μm. Optionally, the distance D between the first terminal D01 and the first dummy signal line 31 may be regarded as a width of the interval between the first terminal D01 and the first dummy signal line 31 along the second direction D2.

Specifically, when the sub-pixels of the display panel are in operation, the scan lines 10 may be used to provide scan signals to the corresponding sub-pixels. In the first end D01 and the second end D02 of the scan line 10, the second end D02 may be electrically connected to other devices or circuits for obtaining scan signals. The first end D01 may not be directly connected to other devices or circuits, and the scan signal may be transmitted to the first end D01 through the second end D02. When the signal line 40 is disposed in the non-display area NA, the signal line 40 may be disposed on a side of the first dummy signal line 31 away from the display area AA. Along the second direction D2, the first end D01 of the scan line 10 is disposed on a side of the first dummy signal line 31 facing the data line 20.

When the distance between the first terminal D01 of the scan line 10 and the first dummy signal line 31 is small, for example, less than 30 μm, the distance between the first terminal D01 and the signal line 40 may also be small. The tip discharge may still occur between the first terminal D01 and the signal line 40. When the distance D between the first terminal D01 and the first dummy signal line 31 is set to be D≥30 μm, the distance between the first terminal D01 and the first dummy signal line 31 is increased. That is, the distance between the first terminal D01 and the signal line 40 is increased. The greater the distance between the first end D01 and the signal line 40, the less likely the tip discharge may occur between the first end D01 and the signal line 40. Accordingly, electrical connection between the scan line 10 and the dummy signal line 30 caused by the static electricity generated by the tip discharge may be avoided, and the display effect of the display panel may thus be improved.

In the present disclosure, the display area AA may be an area not including dummy signal lines and dummy pixels.

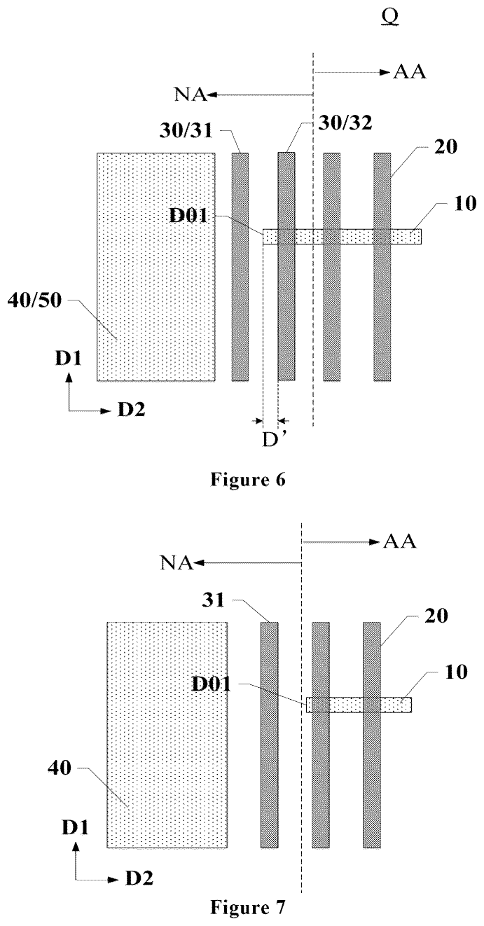

In one embodiment, one dummy signal line 30 is disposed in the non-display area NA on a same side of the display area AA. In some other embodiments of the present disclosure, two or more dummy signal lines 30 may be disposed in the non-display area on a same side of the display area AA. FIG. 6 illustrates another enlarged schematic diagram of area Q of the display panel shown in FIG. 3. Referring to FIG. 6, the dummy signal line 30 between the first dummy signal line 31 and the data line 20 is a second dummy signal line 32. Along the thickness direction of the display panel, the scan line 10 may overlap with the second dummy signal line 32 but do not overlap with the first dummy signal line 31. In this configuration, the first terminal D01 of the scan line 10 is located between the first dummy signal line 31 and the second dummy signal line 32, and the distance D′ between the first terminal D01 and the second dummy signal line 32 is greater than a width of at least one sub-pixel. In this way, a certain distance exists between the first terminal D01 and the second dummy signal line 32. Even when the tip discharge problem occurs at the first terminal D01 of the scan line 10, the static electricity may not break down the insulating layer between the scan line 10 and the second dummy signal line 32. Accordingly, the display effect of the display panel may be improved.

Still referring to FIG. 4, in one embodiment, the first terminal D01 and the first dummy signal line 31 are located in the non-display area NA on a same side of the display area AA.

Specifically, to increase the distance between the first terminal D01 and the first dummy signal line 31 along the second direction D2, a feasible implementation method is to shrink the first terminal D01 of the scan line 10 toward the display area AA, that is, to reduce the distance between the first terminal D01 of the scan line 10 and the edge of the display area AA. In this case, the first terminal D01 is still located in the non-display area NA. When the first terminal D01 is arranged in the non-display area NA, the first terminal D01 may be blocked by a black matrix in the display panel. Accordingly, a problem that the first terminal D01 is visible may be avoided, and the overall display effect of the display panel may thus be improved.

FIG. 7 illustrates an enlarged schematic diagram of a part of scan lines in a non-display area and a display area of the display panel shown in FIG. 3. FIG. 7 shows another feasible arrangement of the first terminal D01 of the scan line 10. Referring to FIG. 7, in one embodiment, the first terminal D01 is located in the display area AA.

In one embodiment, to increase the distance between the first terminal D01 and the first dummy signal line 31 by retracting the first terminal D01 toward the display area AA, the first terminal D01 of the scan line 10 may be shrunk into the display area AA. When the first terminal D01 is located in the display area AA, the distance between the first terminal D01 and the signal line 40 in the non-display area NA is further increased. Accordingly, the phenomenon of tip discharge occurring between the first terminal D01 of the scan line 10 and the signal line 40 may be avoided. It should be noted that, when the first terminal D01 is arranged in the display area AA, the first terminal D01 may be arranged as close to the edge of the display area AA as possible, such that effective electrical connection between the scan line 10 and each corresponding sub-pixel may be achieved.

Still referring to FIG. 3, in one embodiment, the first terminal D01 of each scan line 10 is located between the first dummy signal line 31 and the data line 20.

The display panel may be disposed with hundreds or thousands of scan lines 10. When an electrostatic discharge occurs between the first end D01 of one or a plurality of the scan lines 10 and the signal line 40, the scan line 10 and the dummy signal line 30 overlapping with the scan line 10 may be electrically connected due to electrostatic breakdown. As a result, the display effect of the sub-pixels connected to the scan line 10 may be affected, and the overall display effect of the display panel may thus be affected. In one embodiment, along the second direction D2, the first end of each scan line 10 is arranged between the first dummy signal line 31 and the data line 20. On the one hand, the distance between the first end D01 of the scan line 10 and the signal line 40 in the non-display area NA may be increased. On the other hand, overlapping of the first dummy signal line 31 and the scan line 10 in the thickness direction of the display panel may be avoided. In this way, the phenomenon of tip discharge occurring at the first terminal D01 of each scan line 10 may be avoided, and the electrical connection between the first dummy signal line 31 and the scan line 10 may be avoided. Accordingly, the overall display effect of the display panel may be improved.

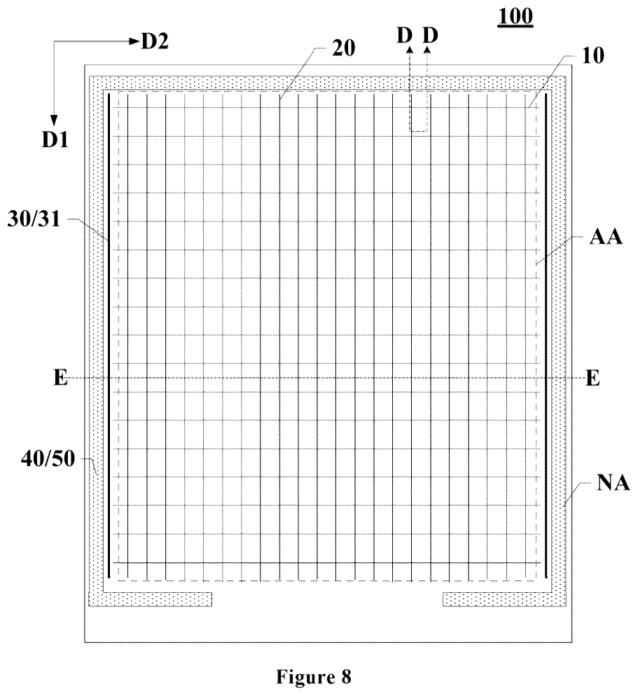

FIG. 8 illustrates another top view of a display panel consistent with the disclosed embodiments of the present disclosure. Referring to FIG. 8, in one embodiment, the display panel also includes a conductive metal portion 50 located in the non-display area NA. The conductive metal portion 50 is disposed at least partially around the display area AA. A width of the conductive metal portion 50 along the second direction D2 is larger than the line width of the scan line 10. In the non-display area NA, the conductive metal portion 50 is located on a side of the first dummy signal line 31 away from the display area AA. The conductive metal portion 50 receives a fixed potential signal.

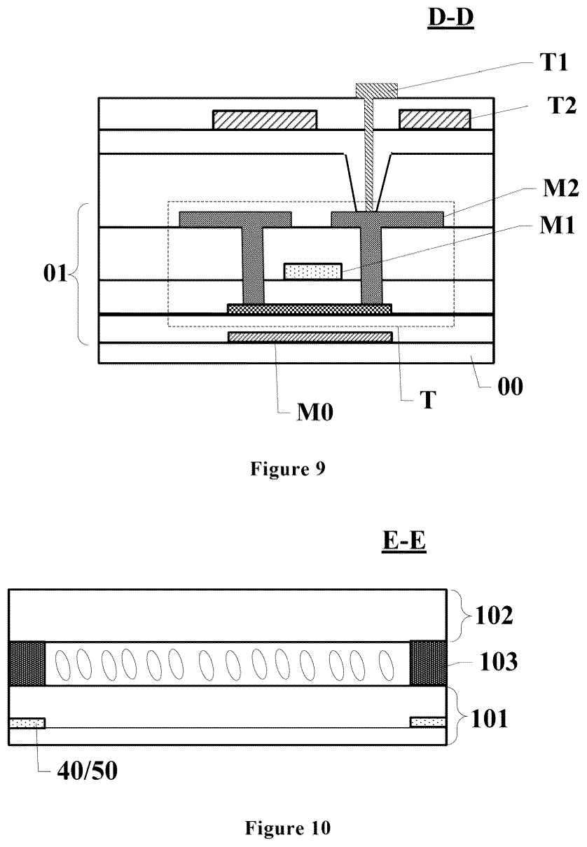

In one embodiment, the signal line 40 may be embodied as the conductive metal portion 50. The conductive metal portion 50 is disposed in the non-display area NA, at least partly surrounding the display area AA, for providing a fixed potential signal to the sub-pixels in the display area AA. The fixed potential signal may be, for example, a common voltage signal. FIG. 9 illustrates a DD cross-sectional view of the display panel shown in FIG. 8. Referring to FIGS. 8 and 9, the display panel includes a driving layer 01, and a pixel electrode T1 and a common electrode T2 disposed on one side of the driving layer 01. The pixel electrode T1 is electrically connected to the driving layer 01 for receiving the driving signal provided by the driving layer 01. The common electrode T2 is electrically connected to the conductive metal portion 50, and is configured for receiving the common voltage signal transmitted by the conductive metal portion 50. The electric field formed between the pixel electrode T1 and the common electrode T2 may be used to drive the liquid crystal to deflect and realize the display function of the display panel.

In one embodiment, the line width of the conductive metal portion 50 along the second direction D2 is larger than the line width of the scan line 10. When the conductive metal portion 50 with a larger line width is used to provide the common voltage signal to the common electrode T2, the impedance of the conductive metal portion 50 may be reduced. As such, the loss of the common voltage during the transmission process may be reduced, the uniformity of signals received by the common electrodes T2 in different regions may be improved, and the overall display uniformity of the display panel may thus be improved. Optionally, the display panel includes an array substrate and an opposite substrate. FIG. 9 only shows a scheme in which the pixel electrode T1 and the common electrode T2 are each disposed on an array substrate of the display panel, and the common electrode T2 is disposed between the pixel electrode T1 and the driving layer 01. The present disclosure does not limit the actual position of the common electrode T2.

In some other embodiments of the present disclosure, when the pixel electrode T1 and the common electrode T2 are each disposed on the array substrate, the common electrode T2 may be disposed on a side of the pixel electrode T1 away from the driving layer 01. In some other embodiments of the present disclosure, the pixel electrode T1 and the common electrode T2 may also be respectively arranged on different substrates. For example, the pixel electrode T1 may be disposed on the array substrate, and the common electrode T2 may be disposed on the opposite substrate.

Optionally, the driving layer 01 includes a transistor T. A gate of the transistor T is located on a first metal layer M1, and a source and a drain of the transistor T are located on a second metal layer M2. Optionally, the scan lines 10 in the display panel are located on the first metal layer M1, and the data lines 20 are located on the second metal layer M2.

Referring to FIGS. 4-9, the line width of the conductive metal portion 50 is relatively large. Compared with the first terminal D01 of the scan line 10, the conductive metal portion 50 in the non-display area NA may be regarded as the signal line 40. The conductive metal portion 50, for example, may be embodied as a bulk metal structure. If the conductive metal portion 50 and the scan line 10 are located on a same layer, and the first end D01 of the scan line 10 is relatively close to the conductive metal portion 50, tip discharge may occur between the first end D01 and the conductive metal portion 50. Accordingly, in one embodiment, the distance between the first terminal D01 and the conductive metal portion 50 is increased by increasing the distance between the first terminal D01 and the first dummy signal line 31. In this way, electrostatic discharge between the first terminal D01 and the conductive metal portion 50 may be avoided.

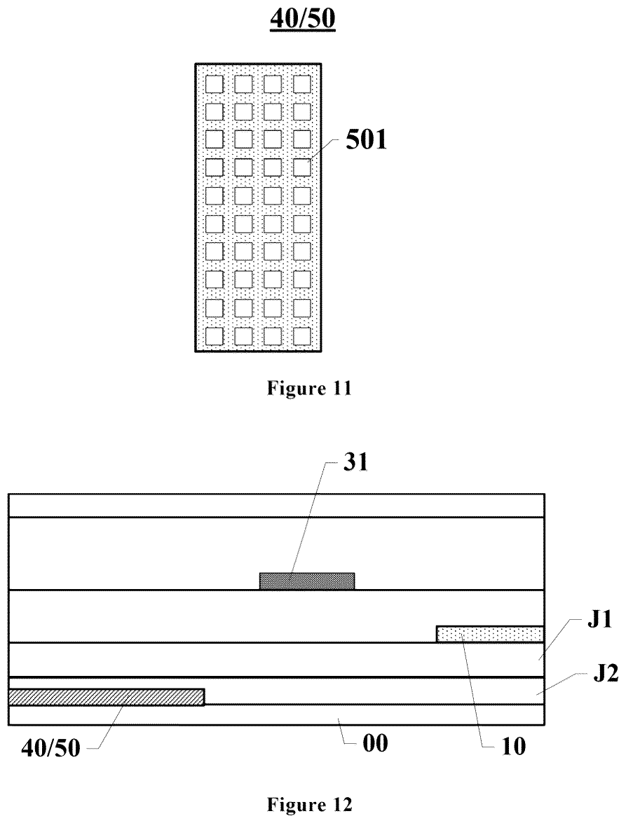

FIG. 10 illustrates an EE cross-sectional view of the display panel in FIG. 8. FIG. 10 shows a relative positional relationship between a first substrate 101 and a second substrate 102 in the display panel. FIG. 11 illustrates a top view of a conductive metal portion consistent with the disclosed embodiments of the present disclosure.

Referring to FIGS. 10 and 11, in one embodiment, the display panel includes a first substrate 101 and a second substrate 102 disposed oppositely to the first substrate 101. Referring to FIGS. 5-9, the substrate 00, the scan lines 10, the data lines 20, the dummy signal lines 30, and the conductive metal portion 50 are each located over the first substrate 101.

In the non-display area NA, a frame glue 103 is disposed between the first substrate 101 and the second substrate 102. Along the thickness direction of the display panel, the conductive metal portion 50 overlaps with the frame glue 103. Referring to FIG. 11, the conductive metal portion 50 includes a plurality of openings 501. The openings 501 penetrate the conductive metal portion 50 along the thickness direction of the conductive metal portion 50. Along the thickness direction of the display panel, the frame glue 103 overlaps the openings 501.

In one embodiment, the display panel is a liquid crystal display panel. The first substrate 101 and the second substrate 102 disposed oppositely to the first substrate are bonded by the frame glue 103 located in the non-display area NA. The space formed by the first substrate 101, the second substrate 102, and the frame glue 103 is filled with liquid crystals.

When bonding the first substrate 101 and the second substrate 102 with the frame glue 103, during the manufacturing process, the frame glue 103 is originally in a liquid form. The frame glue 103 may be cured by irradiating light to the liquid frame glue 103. When a light source for irradiating light to the frame glue 103 is located on a side of the first substrate 101 away from the second substrate 102, since the conductive metal portion 50 is disposed in the non-display area NA, the conductive metal portion 50 may block light and affect the curing of the frame glue 103. Accordingly, in one embodiment, referring to FIG. 11, a plurality of openings 501 are formed on the conductive metal portion 50. Along the thickness direction of the conductive metal portion 50, the openings 501 penetrate through the conductive metal portion 50. The frame glue 103 overlaps the openings 501 along the thickness direction of the display panel. When light is irradiated to the frame glue 103 at the non-display area NA from the side of the first substrate 101 away from the second substrate 102 from, the light may pass through the openings 501 to the frame glue 103. Accordingly, reliable curing of the frame glue 103 may be realized.

Optionally, when the openings 501 are formed on the conductive metal portion 50, the openings 501 may be uniformly arranged on the conductive metal portion 50. For example, the distance between any two adjacent openings 501 may be equal. In this way, light may be evenly irradiated to the frame glue 103, and curing uniformity of the frame glue 103 may thus be improved.

The present disclosure does not limit the shape, size and quantity of the openings 501 on the conductive metal portion 50. In addition to the openings 501 with a square shape as shown in FIG. 11, the openings 501 may have other shapes according to actual needs.

Still referring to FIG. 5, in one embodiment, the conductive metal portion 50 and the scan lines 10 are disposed on a same layer. In this case, one film layer may be used for fabricating the conductive metal portion 50 and the scan line 10, and the conductive metal portion 50 and the scan line 10 may be fabricated in a same fabrication process. Accordingly, the film layer structure of the display panel may be simplified, the manufacturing process of the display panel may be simplified, and the production efficiency may be improved.

When the conductive metal portion 50 and the scan line 10 are disposed on a same layer, the possibility of tip discharge between the first end D01 of the scan line 10 and the conductive metal portion 50 may be high. In the present disclosure, the probability of tip discharge between the first terminal D01 of the scan line 10 and the conductive metal portion 50 may be decreased by increasing the distance between the first terminal D01 of the scan line 10 and the conductive metal portion 50. Moreover, by setting the first scan line G1 and the first dummy signal line 31 not to overlap in the thickness direction of the display panel, the possibility of electrical connection between the scan line 10 and the first dummy signal line 31 caused by the tip discharge may be decreased.

FIG. 12 illustrates a layer relationship diagram of the conductive metal portion 50, the first dummy signal line 31 and the scan line 10 in a first non-display area NA1. Referring to FIG. 12, in one embodiment, along the thickness direction of the display panel, at least one insulating layer is disposed between the film layer where the conductive metal portion 50 is located and the film layer where the scan line 10 is located.

Specifically, as shown in FIG. 12, in one embodiment, the conductive metal portion 50 and the scan line 10 are disposed on different film layers. Along the thickness direction of the display panel, the conductive metal portion 50 is isolated from the first terminal D01 of the scan line 10 by an insulating layer J1 and an insulating layer J2. In this way, the distance between the conductive metal portion 50 and the first terminal D01 of the scan line 10 along the thickness direction of the display panel may be increased. As such, the condition for tip discharge to occur between the first terminal D01 of the scan line 10 and the conductive metal portion 50 may be destroyed. The possibility of tip discharge occurring between the first terminal D01 of the scan line 10 and the conductive metal portion 50 may thus be avoided. Accordingly, the overall display effect of the display panel may be improved.

Referring to FIGS. 9 and 12, the display panel may also include a light-shielding metal M0. The light-shielding metal M0 is located between the substrate 00 and the transistor T. Along the thickness direction of the display panel, the light-shielding metal M0 covers the channel region of the transistor, to prevent the performance of the channel region of the transistor from being changed by the illumination of the backlight. When the conductive metal portion 50 and the scan line 10 are disposed on different film layers, the conductive metal portion 50 and the light-shielding metal M0 may be arranged on a same layer, and the scan line 10 and the gate of the transistor may be arranged on a same layer. In this way, a separate film layer for the conductive metal portion 50 may not be needed. Accordingly, the film layer structure of the display panel may be simplified, and the production efficiency of the display panel may be improved.

Optionally, when the conductive metal portion 50 and the scan line 10 are disposed on different film layers, the conductive metal portion 50 may be disposed on other metal layers in the display panel. For example, the conductive metal portion 50 and the data lines 20 may be disposed on a same layer, and may be produced in a same production process. In this way, a separate film layer for the conductive metal portion 50 may not be needed. Accordingly, the film layer structure of the display panel may be simplified, and the manufacturing process of the display panel may be simplified.

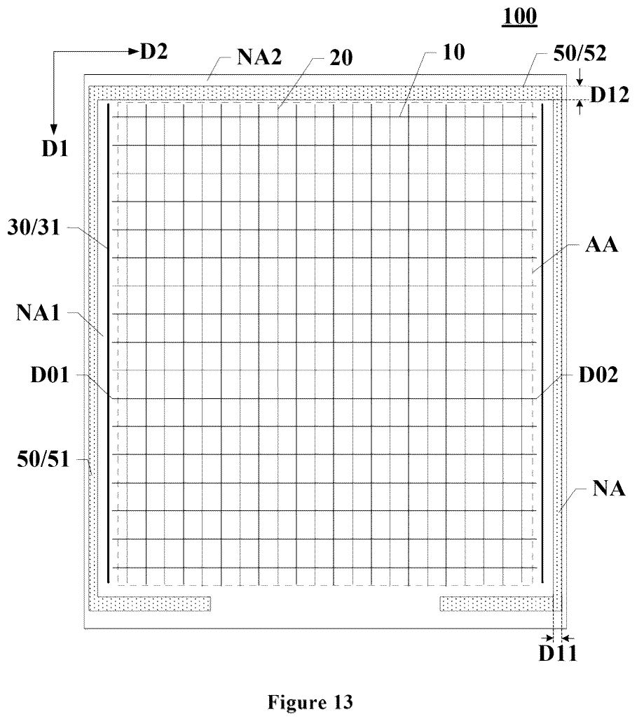

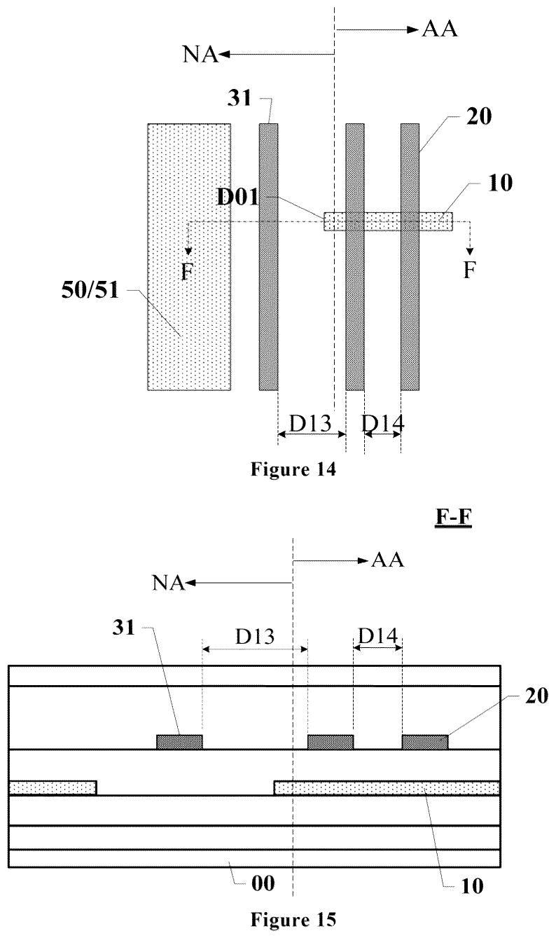

FIG. 13 illustrates another top view of a display panel consistent with the disclosed embodiments of the present disclosure. In the present disclosure, the conductive metal portion 50 may have different line widths. Referring to FIG. 13, in one embodiment, the non-display area NA includes a first non-display area NA1 on one side of the display area AA, arranged along the second direction D2, and a second non-display area NA2 on one side of the display area AA, arranged along the first direction D1. The scan line 10 includes a first terminal D01 and a second terminal D02 oppositely disposed along the second direction D2. The first terminal D01 is disposed in the first non-display area NA1. The conductive metal portion 50 includes a first conductive metal portion 51 located in the first non-display area NA1 and a second conductive metal portion 52 located in the second non-display area NA2. In the first non-display area NA1, the first conductive metal portion 51 is located on a side of the first dummy signal line 31 away from the first terminal D01. A width D11 of the first conductive metal portion 51 is smaller than a width D12 of the second conductive metal portion 52.

Taking FIG. 13 as an example, the first non-display area NA1 may be regarded as at least one of the left frame area and the right frame area of the display panel, and the second non-display area NA2 may be regarded as the upper frame area of the display panel. In existing technology, when making the conductive metal portion 50, the conductive metal portion 50 in the first non-display area NA1 and the conductive metal portion 50 in the second non-display area NA2 may have a same width. In one embodiment of the present disclosure, the conductive metal portions 50 in the first non-display area NA1 and the second non-display area NA2 are designed to have different widths.

Specifically, a width D11 of the first conductive metal portion 51 located in the first non-display area NA1 is set to be smaller than a width D12 of the second conductive metal portion 52 located in the second non-display area NA2. For the first conductive metal portion 51, the width D11 refers to the width of the first conductive metal portion 51 along the second direction D2. For the second conductive metal portion 52, the width D12 refers to the width of the second conductive metal portion 52 along the first direction D1. When the width of the first conductive metal portion 51 in the first non-display area NA1 is reduced, the space occupied by the first conductive metal portion 51 in the first non-display area NA1 is reduced. On the premise that the frame width of the first non-display area NA1 remains unchanged, the edge of the first conductive metal portion 51 close to the display area AA may be moved outward in a direction away from the display area AA. As a result, the distance between the first conductive metal portion 51 and the first terminal D01 of the scan line 10 may be increased. Accordingly, electrostatic discharge between the first conductive metal portion 51 and the first terminal D01 of the scan line 10 may be avoided.

FIG. 14 illustrates a diagram of a relative position relationship among the first conductive metal portion 51, the first dummy signal line 31, the data line 20, and the scan line 10. FIG. 15 illustrates an FF direction cross-sectional view of FIG. 14.

Referring to FIGS. 14 and 15, in one embodiment, the first dummy signal line 31 and the data line 20 are disposed on a same film layer. In the film layer where the first dummy signal line 31 is disposed, along the second direction D2, a distance D13 between the first dummy signal line 31 and another signal line adjacent to the first dummy signal line 31 is greater than a distance D14 between two adjacent data lines 20.

Optionally, the first conductive metal portion 51 and the data line 20 are disposed in different film layers, and the data line 20 and the first dummy signal line 31 are disposed in a same film layer. In the film layer where the data line 20 is disposed, the first dummy signal line 31 is the dummy signal line farthest from the data line, and the another signal line adjacent to the first dummy signal line 31 refers to the data line 20.

In one embodiment, the distance D13 between the first dummy signal line 31 and the another signal line adjacent to the first dummy signal line 31 is set to be greater than the distance D14 between two adjacent data lines 20. That is, the first dummy signal line 31 is moved away from the display area AA along the second direction D2. When the width of the first conductive metal portion 51 in the first non-display area NA1 is reduced, a space may be provided for the first dummy signal line 31 to move outward. As such, the distance between the first dummy signal line 31 and the first terminal D01 of the scan line 10 may be increased, and overlap between the first dummy signal line 31 and the scan line 10 in the thickness direction of the display panel may be avoided. When the first terminal D01 of the scan line 10 is further retracted toward the display area AA, the distance between the first terminal D01 of the scan line 10 and the first dummy signal line 31 may be increased. The possibility of overlapping between the between the first terminal D01 of the scan line 10 and the first dummy signal line 31 may be further reduced. In addition, the distance between the first terminal D01 of the scan line 10 and the first conductive metal portion 51 may be further increased. The phenomenon of electrostatic discharge between the first terminal D01 of the scan line 10 and the first conductive metal portion 51 may be avoided.

Optionally, the distance between the first dummy signal line 31 and the another signal line adjacent to the first dummy signal line 31 refers to a width of an interval between the first dummy signal line 31 and the another signal line adjacent to the first dummy signal line 31. The distance between two adjacent data lines 20 refers to a width of the interval between two adjacent data lines 20.

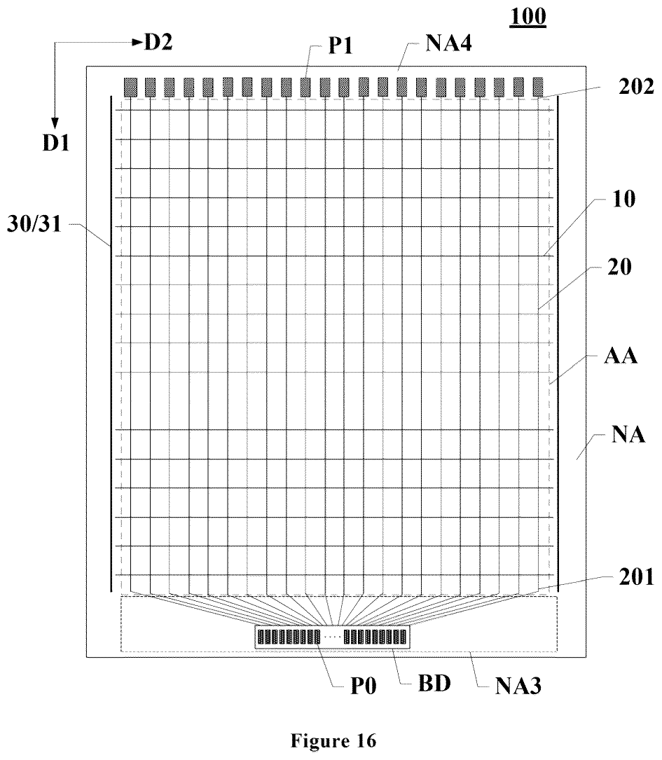

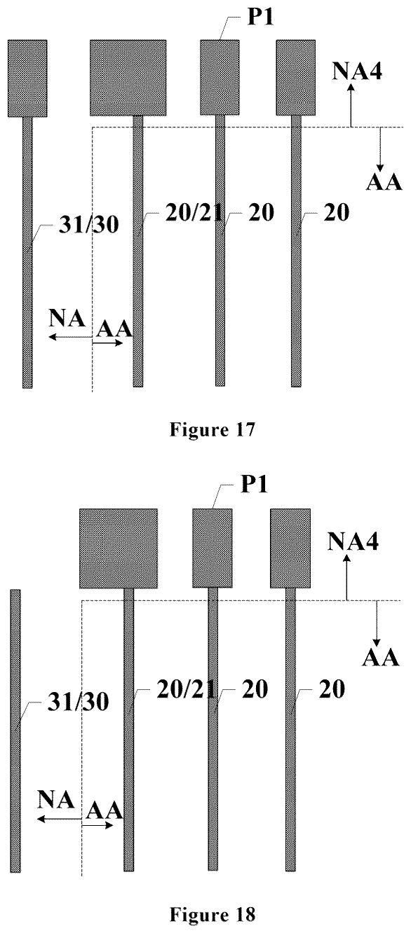

FIG. 16 illustrates another top view of a display panel consistent with the disclosed embodiments of the present disclosure. FIG. 17 illustrates a partial enlarged view of a fourth non-display area NA4 and a part of a display area AA adjacent to the fourth non-display area NA4 in the display panel. Referring to FIGS. 16 and 17, in one embodiment, the data line 20 includes a first end 201 and a second end 202 oppositely arranged along the first direction D1. The non-display area includes a third non-display area NA3 and a fourth non-display area NA4 arranged on two sides of the display area AA along the first direction D1. The third non-display area NA3 includes a binding area BD. The binding area BD includes a plurality of conductive bonding pads P0. The fourth non-display area NA4 includes a plurality of detection bonding pads P1. The first end of the data line 20 is electrically connected to the conductive bonding pad P0, and the second end of the data line 20 is electrically connected to the detection bonding pad P1. The data line 20 includes a first data line 21 adjacent to the dummy signal line 30. An area of the detection bonding pad P1 connected to the first data line 21 is larger than an area of the detection bonding pad P1 connected to other data lines 20.

Specifically, the third non-display area NA3 may be regarded as a lower frame area of the display panel. The lower frame area is disposed with the binding area BD. The conductive bonding pad P0 in the binding area BD may be used for binding a driving chip or a flexible circuit board. The fourth non-display area NA4 may be regarded as an upper frame area of the display panel. A plurality of detection bonding pads P1 is disposed in the upper frame area. Each data line 20 is electrically connected to one detection bonding pad P1. When a probe is in contact with the detection bonding pad P1, signal information of the second end 202 of the data line 20 may be obtained. Accordingly, signals at the first end 201 of the data line 20 may be compared with signals at the second end 202, to detect whether the data line 20 transmits signals normally.

In existing technology, along the arrangement direction of the detection bonding pads P1, the distance between two adjacent detection bonding pads P1 is equal. When the first dummy signal line 31 adjacent to the data line 20 is moved away from the display area AA, the distance between the first dummy signal line 31 and the data line 20 is increased. The first data line 21 refers to the data line 20 adjacent to the dummy signal line 30. Since the first dummy signal line 31 adjacent to the first data line 21 is moved outward, the distance between the first dummy signal line 31 and the first data line 21 is increased, providing a space for increasing the area of the detection bonding pad P1 connected to the first data line 21. Accordingly, the area of the detection bonding pad P1 connected to the first data line 21 may be increased. A probe may be electrically connected to the detection bonding pad P1 to detect the signal on the first data line 21. When the area of the detection bonding pad PI is increased, difficulty of the electrical connection between the probe and the detection bonding pad PI may be reduced. As a result, the detection efficiency may be improved.

Optionally, the dummy signal line 30 is also electrically connected to the detection bonding pad P1 to achieve visual uniformity of the display panel. FIG. 18 illustrates another partial enlarged view of a fourth non-display area NA4 and a part of a display area AA adjacent to the fourth non-display area NA4 in the display panel. Referring to FIG. 18, in some other embodiments of the present disclosure, when the dummy signal line 30 is in a floating state, no detection bonding pad may be provided for the dummy signal line 30.

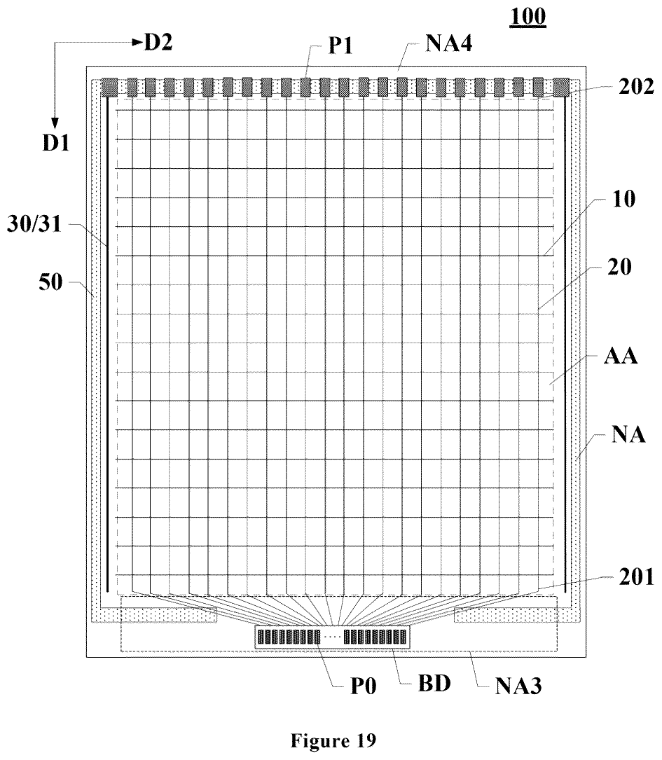

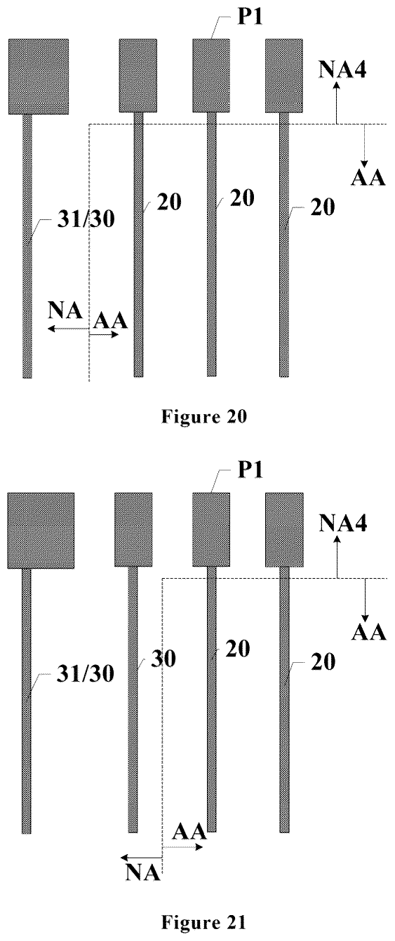

FIG. 19 illustrates another top view of a display panel consistent with the disclosed embodiments of the present disclosure. FIG. 20 illustrates another partial enlarged view of a fourth non-display area NA4 and a part of a display area AA adjacent to the fourth non-display area NA4 in the display panel. Referring to FIGS. 19 and 20, in one embodiment, the display panel also includes a conductive metal portion 50 located in the non-display area NA. The conductive metal portion 50 is arranged at least partially surrounding the display area AA. In the non-display area NA, the conductive metal portion 50 is located on a side of the first dummy signal line 31 away from the display area AA. The conductive metal portion 50 may receive a fixed potential signal, and the conductive metal portion 50 may be electrically connected to the first dummy signal line 31.

The data line 20 includes a first end 201 and a second end 202 oppositely disposed along the first direction D1. The non-display area includes a third non-display area NA3 and a fourth non-display area NA4 disposed on two sides of the display area AA, along the first direction D1. The third non-display area NA3 includes a binding area BD. The binding area BD includes a plurality of conductive bonding pads P0. The fourth non-display area NA4 includes a plurality of detection bonding pads P1. The first end 201 of the data line 20 is electrically connected to the conductive bonding pad P0. The second end 202 of the data line 20 is electrically connected to the detection bonding pad P1.

The first dummy signal line 31 is electrically connected to the detection bonding pad P1 in the fourth non-display area NA4. The area of the detection bonding pad P1 connected to the first dummy signal line 31 is larger than the area of the detection bonding pad P1 connected to the data line 20.

Specifically, in one embodiment, the dummy signal line 30 (the first dummy signal line 31) closest to the conductive metal portion 50 may be multiplexed as a common signal line connected to the conductive metal portion 50. Referring to FIG. 19, the first dummy signal line 31 may be electrically connected to the conductive metal portion 50 for transmitting the common signal on the conductive metal portion 50 to the sub-pixels in the display area. In this case, no additional signal wires electrically connected to the conductive metal portion 50 in the display panel may be needed. Accordingly, wiring of the display panel may be simplified.

In existing technology, along the arrangement direction of the detection bonding pads P1, the distance between two adjacent detection bonding pads P1 is equal. When the first dummy signal line 31 is moved away from the display area AA, the distance between the first dummy signal line 31 and the data line 20 is increased, providing an increased space for the detection bonding pad P1 connected to the first dummy signal line 31. In this way, the area of the detection bonding pad P1 connected to the first dummy signal line 31 may be increased. A probe may be electrically connected to the detection bonding pad P1 to detect signals on the first dummy signal line 31. When the area of the detection bonding pad P1 is increased, difficulty of the electrical connection between the probe and the detection bonding pad PI may be reduced. As a result, the detection efficiency may be improved.

In one embodiment, as shown in FIG. 20, one dummy signal line 30 is disposed in the non-display area on a same side of the display area. In some other embodiments of the present disclosure, two or more dummy signal lines 30 may be disposed in the non-display area NA on a same side of the display area AA. FIG. 21 illustrates another partial enlarged view of a fourth non-display area NA4 and a part of a display area AA adjacent to the fourth non-display area NA4 in the display panel. Referring to FIG. 21, two dummy signal lines 30 are disposed in the non-display area NA on a same side of the display area AA. In this case, the first dummy signal line 31 located on the outermost periphery may be multiplexed as a common signal line and electrically connected to the conductive metal portion.

It should be noted that the display area is provided with sub-pixels that may actually perform a display function. Compared with the data lines in the display area, the dummy signal lines are not electrically connected to the sub-pixels in the display area. The dummy signal lines are disposed in the non-display area.

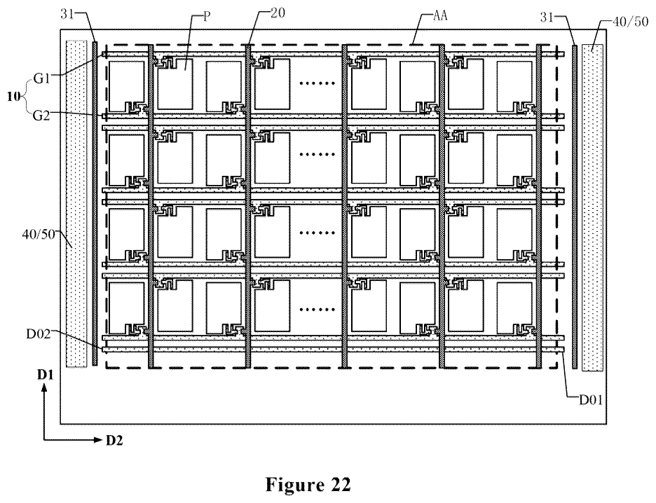

FIG. 22 illustrates a schematic connection diagram of a scan line and a sub-pixel in a display panel consistent with the disclosed embodiments of the present disclosure. Referring to FIG. 22, in one embodiment, the display panel includes a plurality of sub-pixels P arranged in an array along the first direction D1 and the second direction D2. Among the sub-pixels P located in a same row along the second direction D2, a part of the sub-pixels P are electrically connected to one scan line 10/G1, and another part of the sub-pixels P are electrically connected to another scan line 10/G2. The scan line 10 includes a first terminal D01 and a second terminal D02 opposite to each other along the second direction D2. The first ends D01 of the two scan lines 10 connected to a same row of sub-pixels P are each located between the first dummy signal line 31 and the second ends D02.

Specifically, in one embodiment, the sub-pixels P located in a same row are connected to two scan lines 10. In this case, two adjacent columns of sub-pixels may be connected to a same data line 20. Compared with the way in existing technology that one column of sub-pixels corresponds to one data line 20, the quantity of data lines 20 included in the display panel may be reduced, and the cost of the driving circuits (IC) connected to the data lines 20 may be reduced correspondingly. Accordingly, the cost of the product may be reduced.

When a row of sub-pixels is electrically connected to two scan lines 10, the quantity of scan lines 10 in the display panel may be increased compared to a connection method in which a row of sub-pixels corresponds to one scan line 10. When the first end D01 of the scan line 10 is close to the signal line 40 in the non-display area NA, the phenomenon of tip discharge may occur. The greater the quantity of the scan lines 10, the greater the possibility of tip discharge, and the greater the possibility of electrical connection between the scan lines 10 and the first dummy signal lines 31 due to static electricity. Accordingly, in one embodiment, the first terminal D01 of each scan line 10 is arranged between the first dummy signal line 31 and the second terminal D02. That is, the scan line 10 and the first dummy signal line 31 do not overlap in the thickness direction of the display panel, and simultaneously, the distance between the first terminal D01 of the scan line 10 and the signal line 40 in the non-display area NA is also increased. In this way, even if the quantity of the scan lines 10 included in the display panel is large, the possibility of tip discharge occurring between the first end D01 of the scan line 10 and the signal lines 40 may still be reduced. Simultaneously, the electrical connection between the scan line 10 and the first dummy signal line 31 due to electrostatic breakdown may also be avoided. Accordingly, the overall display effect of the display panel may be improved.

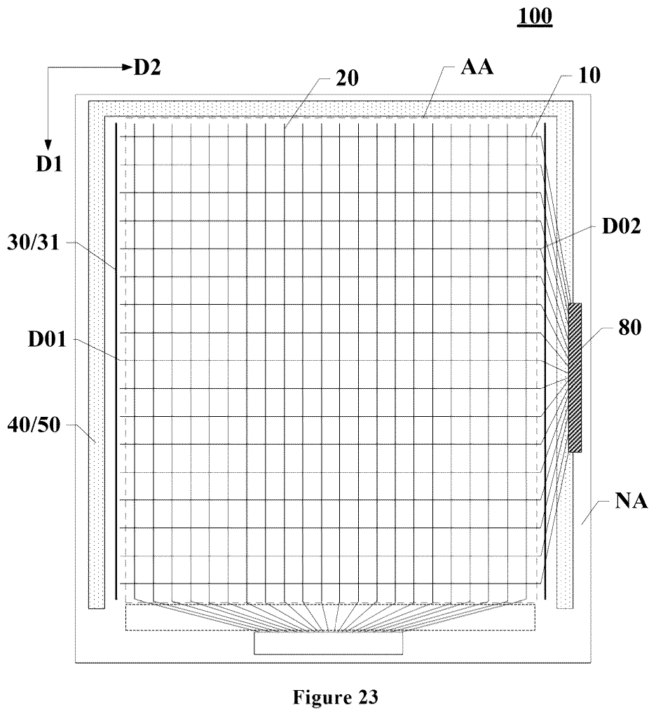

FIG. 23 illustrates another schematic structural diagram of a display panel consistent with the disclosed embodiments of the present disclosure. Referring to FIG. 23, in one embodiment, the scan line 10 includes a first terminal D01 and a second terminal D02 opposite to each other along the second direction D2. The first terminal D01 is located between the first dummy signal line 31 and the data line 20. The display panel also includes a gate driving chip 80 disposed in the non-display area NA, and the second terminal D02 is electrically connected to the gate driving chip 80.

FIG. 23 shows a way for the scan line 10 to acquire scan signals. Specifically, the gate driving chip 80 is disposed in the non-display area NA of the display panel. The gate driving chip 80 may be disposed in the non-display area NA on one side of the display area AA along the second direction D2. In one embodiment, as an example for illustration, the gate driving chip 80 is located at the right frame of the display panel. The second terminal D02 of the scan line 10 is electrically connected to the gate driving chip 80 and obtains the scan signal through the gate driving chip 80. The first terminal D01 of the scan line 10 may be located in another non-display area NA opposite to the gate driving chip 80, for example, in the left frame of the display panel. Further, the first terminal D01 of the scan line 10 is located between the first dummy signal line 31 and the data line 20. In this way, overlapping between the scan line 10 and the first dummy signal line 31 in the thickness direction of the display panel may be avoided, and the problem of electrical connection between the scan line 10 and the first dummy signal line 31 due to electrostatic breakdown may be avoided. Accordingly, generation of display dark lines may be avoided, and the overall display effect of the display panel may be improved.

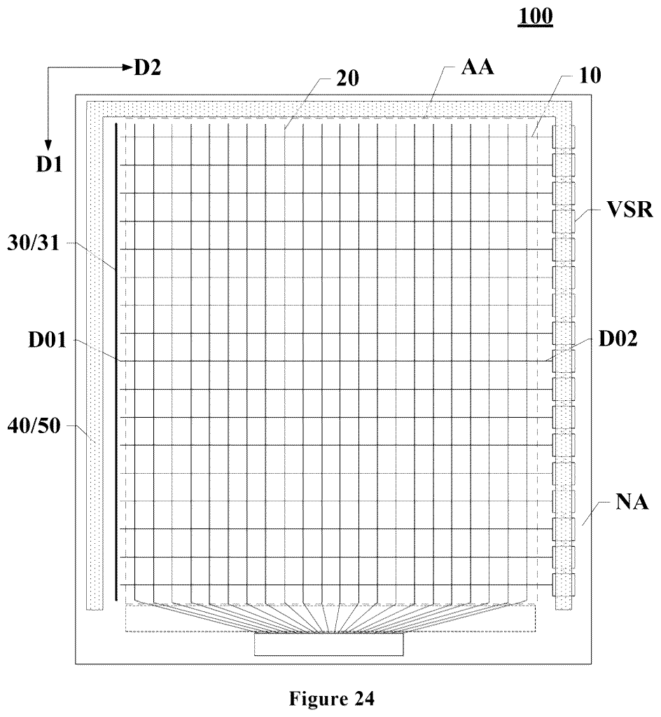

FIG. 24 illustrates another schematic structural diagram of a display panel consistent with the disclosed embodiments of the present disclosure. Referring to FIG. 24, in one embodiment, the scan line 10 includes a first terminal D01 and a second terminal D02 opposite to each other along the second direction D2. The first terminal D01 is located between the first dummy signal line 31 and the data line 20. The display panel also includes a cascaded gate driving circuit VSR. The gate driving circuit VSR is located in the non-display area NA. The second end D02 of the scan line 10 is electrically connected to the gate driving circuit VSR. Optionally, the first end D01 may be regarded as an end of the scan line 10 that is not directly connected to the gate driving circuit VSR. The first end D01 may obtain signals transmitted by the gate driving circuit VSR through the second end D02.

Specifically, in one embodiment, the scan line 10 is electrically connected to the gate driving circuit. In the non-display area NA on a side of the display area AA along the second direction D2, a cascaded gate driving circuit VSR is disposed. For a same scan line 10, the second end D02 is electrically connected to the gate driving circuit VSR, and the first dummy signal line 31 adjacent to the first terminal D01 is disposed in another non-display area NA opposite to the non-display area NA where the gate driving circuit VSR is disposed.

In one embodiment, the scan line 10 may obtain scan signals through the cascaded gate driving circuit VSR. In the first scan line G1, the first terminal D01 not directly connected to the gate driving circuit VSR is located between the first dummy signal line 31 and the data line 20. The distance between the first terminal D01 of the scan line 10 and the signal line 40 in the non-display area NA may be increased. The overlapping between the first terminal D01 and the first dummy signal line 31 in the thickness direction of the display panel may be avoided. The electrical connection between the first dummy signal line 31 and the scan line 10 due to static electricity may be avoided, and the overall display effect of the display panel may be improved.

In one embodiment, an output terminal of the gate driving circuit VSR is electrically connected to the second end D02 of the scan line 10 through a connection hole. The second terminal D02 is located between the first dummy signal line 31 and the data line 20.

In one configuration, the second end D02 of the scan line 10 is electrically connected to an output terminal of the gate driving circuit VSR through a connection hole. In the non-display area NA, the signal line 40 and the scan line 10 are disposed on a same layer. The signal line 40 may be, for example, a signal line connected to the gate driving circuit VSR. Electrostatic discharge may occur between the second terminal D02 of the scan line 10 and the signal line 40. When the second terminal D02 of the scan line 10 overlaps with the first dummy signal line 31 in the non-display area NA, static electricity may cause electrical connection between the scan line 10 and the first dummy signal line 31, resulting in abnormal display of the display panel.

In one embodiment, the second terminal D02 of the scan line 10 is disposed between the first dummy signal line 31 and the data line 20. As such, the distance between the second terminal D02 and the first dummy signal line 31 may be increased, and simultaneously the distance between the second terminal D02 and the signal line 40 in the non-display area NA may be increased. As s result, the possibility of tip discharge between the second terminal D02 and the signal line 40 may be reduced. In addition, the scan line 10 may be prevented from overlapping with the first dummy signal line 31 in the thickness direction of the display panel. Accordingly, the electrical connection between the scan line 10 and the first dummy signal line 31 caused by the electrostatic breakdown may be avoided, and the display effect of the display panel may be improved.

Referring to FIG. 24, in one embodiment, the gate driving circuit VSR is disposed in a non-display area NA on a same side of the display area AA along the second direction D2.

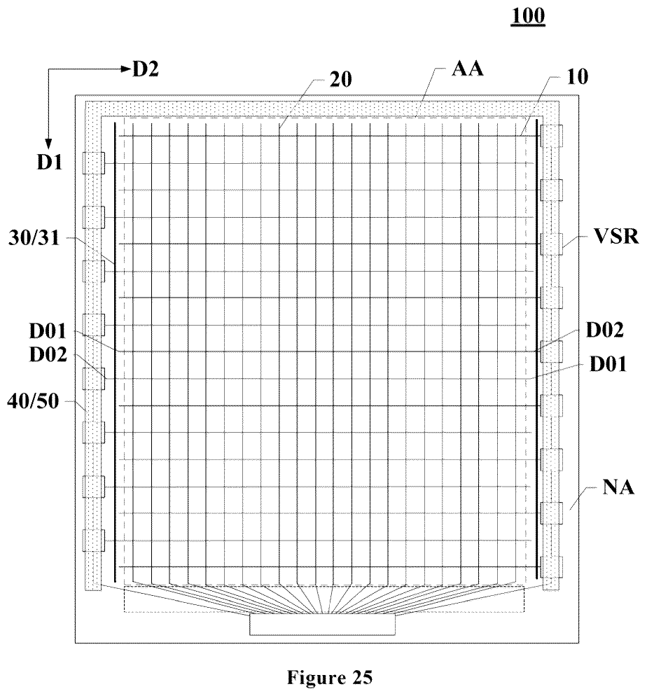

FIG. 25 illustrates another schematic structural diagram of a display panel consistent with the disclosed embodiments of the present disclosure. Referring to FIG. 25, in one embodiment, the gate driving circuit VSR is distributed in non-display areas NA on two opposite sides of the display area AA along the second direction D2. Odd-numbered scan lines 10 are electrically connected to the gate driving circuit VSR located on a same side of the display area AA. Even-numbered scan lines 10 are electrically connected to the gate driving circuit VSR located on the other side of the display area AA.

Specifically, in one embodiment, the scan line 10 is connected to the gate driving circuit VSR to obtain scan signals. The gate driving circuit VSR connected to each scan line 10 in the display panel may be disposed in the non-display area NA on a same side of the display area AA along the second direction D2. Referring to FIG. 24, the second end D02 of each scan line 10 is electrically connected to the gate driving circuit VSR, and the first end D01 of each scan line 10 is located on a same side of each the data lines 20 in the display area AA. In this way, a part of line segments in the scan line 10 may be removed such that the first terminal D01 of the scan line may be located between the first dummy signal line 31 and the data line 20. One end of each scan line 10 located on a same side of the data lines 20 may be uniformly processed such that the first terminal D01 of each scan line 10 may be located between a same first dummy signal line 31 and the data line 20. As such, overlapping between the first scan line G1 and the first dummy signal line 31 in the thickness direction of the display panel may be avoided. By uniformly processing one end of each scan line 10 located on a same side of the data lines 20, the manufacturing process of the scan lines 10 in the display panel may be simplified.

In some other embodiments of the present disclosure, referring to FIG. 25, the gate driving circuit VSR connected to the scan line 10 may be disposed on the two side frames of the display panel. When electrically connecting the gate driving circuit VSR to the scan line 10, the gate driving circuit VSR located on the first side of the display area AA along the second direction D2 is connected to the odd-numbered rows of scan lines 10, and the gate driving circuit VSR located on the second side of the display area AA along the second direction D2 is connected to the even-numbered rows of scan lines 10. In this way, the gate driving circuit VSR may be evenly distributed in the frame areas on two sides of the display panel, and thus the width uniformity of the frames on two sides of the display panel may be improved.

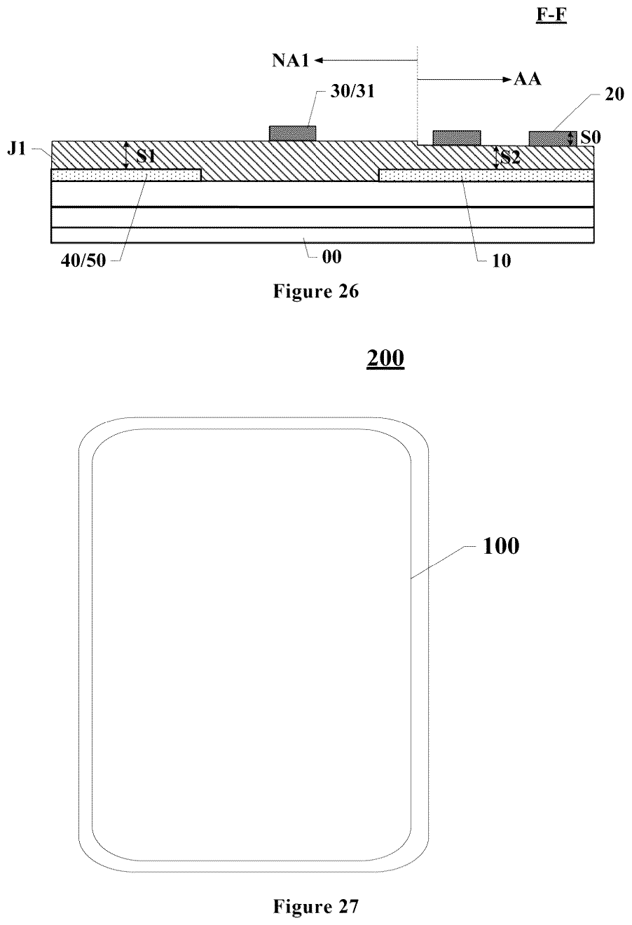

FIG. 26 illustrates an FF direction cross-sectional view of FIG. 14, consistent with the disclosed embodiments of the present disclosure. FIG. 26 shows a scheme of differentiated design of the first insulating layer J1 in the first non-display area NA1 and the display area AA.

Referring to FIG. 26, in one embodiment, the non-display area NA includes a first non-display area NA1 located on at least one side of the display area AA along the second direction D2. Along the direction perpendicular to the plane where the substrate is located, a first insulating layer J1 is disposed between the film layer where the scan line 10 is located and the film layer where the dummy signal line 30 is located. In the first non-display area NA1, the thickness of the first insulating layer J1 is S1. In the display area AA, the thickness of the first insulating layer J1 is S2, where S1>S2.

Specifically, the first dummy signal line 31 is disposed in the non-display area NA. When the thickness of the first insulating layer J1 in the non-display area NA is made greater, for example, greater than the thickness of the first insulating layer J1 in the display area AA, the distance between the first dummy signal line 31 and the scan line 10 along the thickness direction of the display panel may be increased. Even when static interference occurs, since the vertical distance between the first dummy signal line 31 and the scan line 10 is relatively large, the first insulating layer J1 may not be broken down by static electricity. Accordingly, the display dark lines due to the electrical connection between the first dummy signal line 31 and the scan line 10 caused by static electricity may be avoided. As such, the display effect of the display panel may be improved.

Still referring to FIG. 26, in one embodiment, the film layer where the dummy signal line 30 is located has a thickness of S0, where S0≥S1-S2. The dummy signal line 30 is disposed on a side of the first insulating layer J1 away from the substrate. The problem of electrical connection between the first dummy signal line 31 and the scan line 10 caused by static electricity may be avoided by increasing the thickness of the first insulating layer J1 in the first non-display area NA1. The present disclosure further defines that the thickness difference between the first insulating layer J1 in the first non-display area NA1 and the first insulating layer J1 in the display area AA is less than or equal to the thickness S0 of the film layer where the dummy signal line 30 is located. In this way, even if a height difference exists between the first insulating layer J1 in the display area AA and the first non-display area NA1, metal wiring (such as dummy signal lines 30 and data selection 20) may be disposed on the first insulating layer J1. When the metal wiring is disposed in an area with a height difference, the thickness of the metal wiring may compensate for the height difference. That is, the metal wiring disposed in the area with a height difference may not be disconnected. Accordingly, reliability of signal transmission by the metal wiring disposed on the first insulating layer J1 may be improved.

The present disclosure also provides a display device. FIG. 27 illustrates a schematic structural diagram of a display device consistent with the disclosed embodiments of the present disclosure. Referring to FIG. 27, the display device 200 includes a display panel 100 provided by the present disclosure.

It may be understood that, the display device provided by the present disclosure may be a computer, a mobile phone, a tablet and other display devices with a display function. The present disclosure does not specifically limit types of the display device. The display device provided by the present disclosure may have beneficial effects of the display panel provided the present disclosure. For detail, reference may be made to specific descriptions of the display panels in the present disclosure. The present disclosure will not go into detail in this regard.

As disclosed, the technical solutions of the present disclosure have the following advantages.

The display panel and the display device provided by the present disclosure include scan lines and data lines intersecting the scan lines. The data lines extend along the first direction, and the scan lines extend along the second direction. The data lines are disposed in the display area and are configured to provide data signals to the sub-pixels. The scan lines are configured to provide scan signals to the sub-pixels. Dummy signal lines are disposed in the non-display area, and the dummy signal lines are parallel to the data lines. The first dummy signal line is the dummy signal line farthest from the data lines. Since the extension direction of the scan line overlaps with the data line, the end of the scan line may extend to the non-display area. When the non-display area is disposed with a metal signal line, the phenomenon of tip discharge may occur at the end of the scan line. When the terminal overlaps with the first dummy signal line in the thickness direction of the display panel, static electricity may break down the insulating layer between the terminal of the scan line and the first dummy signal line. As a result, the scan line may be electrically connected to the first dummy signal line, thereby affecting the normal display of the sub-pixels connected to the scan line.

In the present disclosure, the end of the scan line is arranged between the first dummy signal line and the data line, and overlapping between the scan line and the first dummy signal line in the thickness direction of the display panel may be avoided. In this way, the distance along the second direction between the end of the scan line and the edge of the non-display area may be increased, and possibility of tip discharge may be reduced. In addition, the electrical connection between the end of the scan line and the first dummy signal line caused by tip discharge may be avoided, and the problem of abnormal display caused by the electrical connection between the scan line and the first dummy signal line may be avoided. Accordingly, impacts of static electricity on the display effect may be avoided.

The embodiments disclosed herein are exemplary only and not limiting the scope of the present disclosure. Various combinations, alternations, modifications, equivalents, or improvements to the technical solutions of the disclosed embodiments may be obvious to those skilled in the art. Without departing from the spirit and scope of this disclosure, such combinations, alternations, modifications, equivalents, or improvements to the disclosed embodiments are encompassed within the scope of the present disclosure.

What is claimed is:

1. A display panel, including a display area and a non-display area surrounding the display area, comprising:
a substrate;
a plurality of scan lines and a plurality of data lines disposed over the substrate, wherein the plurality of data lines is disposed in the display area, the plurality of data lines extends along a first direction and is arranged along a second direction, and the plurality of scan lines extends along the second direction and is arranged along the first direction, wherein the first direction and the second direction intersect; and
at least one dummy signal line disposed in the non-display area, wherein the at least one dummy signal line is parallel to the plurality of data lines, the at least one dummy signal line includes a first dummy signal line that is closest to an outer edge of the non-display area among the at least one dummy signal line, and along the second direction, one end of at least one scan line of the plurality of scan lines is located between the first dummy signal line and the plurality of data lines.

2. The display panel according to claim 1, wherein:
a scan line of the plurality of scan lines includes a first terminal and a second terminal opposite to each other along the second direction;
the first terminal is located between the first dummy signal line and the plurality of data lines; and
a distance between the first terminal and the first dummy signal line is D, with D≥30 μm.

3. The display panel according to claim 2, wherein:
the first terminal and the first dummy signal line are located in the non-display area on a same side of the display area; or
the first terminal is located in the display area.

4. The display panel according to claim 2, wherein:
the first terminal of each scan line of the plurality of scan lines is located between the first dummy signal line and the plurality of data lines.

5. The display panel according to claim 1, further comprising a conductive metal portion located in the non-display area, wherein:
the conductive metal portion is disposed at least partially surrounding the display area, and a width, along the second direction, of the conductive metal portion is larger than a line width of a scan line of the plurality of scan lines;
in the non-display area, the conductive metal portion is located on a side of the first dummy signal line away from the display area; and
the conductive metal portion receives a fixed potential signal.

6. The display panel according to claim 5, further comprising a first substrate and a second substrate disposed oppositely to the first substrate, wherein:
the substrate, the plurality of scan lines, the plurality of data lines, the dummy signal lines, and the conductive metal portion are each located over the first substrate;
in the non-display area, a frame glue is disposed between the first substrate and the second substrate, and along a thickness direction of the display panel, the conductive metal portion overlaps with the frame glue;
the conductive metal portion includes a plurality of openings, and the plurality of openings penetrates the conductive metal portion along a thickness direction of the conductive metal portion; and
along the thickness direction of the display panel, the frame glue overlaps with the plurality of openings.

7. The display panel according to claim 5, wherein:
the conductive metal portion and the plurality of scan lines are disposed on a same layer.

8. The display panel according to claim 5, wherein:
along a thickness direction of the display panel, at least one insulating layer is disposed between a film layer where the conductive metal portion is located and a film layer where the scan line is located.

9. The display panel according to claim 5, wherein:
the non-display area includes a first non-display area on a side of the display area arranged along the second direction, and a second non-display area on a side of the display area arranged along the first direction;
the scan line includes a first terminal and a second terminal oppositely disposed along the second direction, and the first terminal is located in the first non-display area;
the conductive metal portion includes a first conductive metal portion located in the first non-display area and a second conductive metal portion located in the second non-display area;
in the first non-display area, the first conductive metal portion is disposed on a side of the first dummy signal line away from the first terminal; and
a width of the first conductive metal portion is smaller than a width of the second conductive metal portion.

10. The display panel according to claim 9, wherein:
the first dummy signal line and the plurality of data lines are disposed on a same film layer; and
in a film layer where the first dummy signal line is disposed, along the second direction, a distance between the first dummy signal line and another signal line adjacent to the first dummy signal line is greater than a distance between two adjacent data lines of the plurality of data lines.

11. The display panel according to claim 10, wherein:
a data line of the plurality of data lines includes a first end and a second end oppositely arranged along the first direction;
the display panel includes a third non-display area and a fourth non-display area arranged on two sides of the display area along the first direction, wherein the third non-display area includes a binding area, the binding area includes a plurality of conductive bonding pads, and the fourth non-display area includes a plurality of detection bonding pads;
the first end of the data line is electrically connected to the conductive bonding pad, and the second end of the data line is electrically connected to the detection bonding pad; and
the data line includes a first data line adjacent to the dummy signal line, and an area of the detection bonding pad connected to the first data line is larger than an area of the detection bonding pad connected to other data lines.

12. The display panel according to claim 1, further comprising a conductive metal portion disposed in the non-display area, at least partially surrounding the display area, wherein:
in the non-display area, the conductive metal portion is located on a side of the first dummy signal line away from the display area, the conductive metal portion receives a fixed potential signal, and the conductive metal portion is electrically connected to the first dummy signal line;
a data line of the plurality of data lines includes a first end and a second end oppositely arranged along the first direction, and the display panel includes a third non-display area and a fourth non-display area arranged on two sides of the display area along the first direction, wherein the third non-display area includes a binding area, the binding area includes a plurality of conductive bonding pads, and the fourth non-display area includes a plurality of detection bonding pads; and
the first dummy signal line is electrically connected to a detection bonding pad of the plurality of the plurality of detection bonding pads in the fourth non-display area, and an area of the detection bonding pad connected to the first dummy signal line is larger than an area of the detection bonding pad connected to the data line.

13. The display panel according to claim 1, further comprising a plurality of sub-pixels arranged in an array along the first direction and the second direction, wherein:
among the sub-pixels located in a same row along the second direction, a part of the sub-pixels is electrically connected to one scan line of the plurality of scan lines, and another part of the sub-pixels is electrically connected to another scan line of the plurality of the scan lines; and
a scan line of the plurality of scan lines includes a first terminal and a second terminal opposite to each other along the second direction, wherein the first ends of two scan lines connected to a same row of sub-pixels are each located between the first dummy signal line and the second ends.

14. The display panel according to claim 1, further comprising a gate driving chip disposed in the non-display area, wherein:
a scan line of the plurality of scan lines includes a first terminal and a second terminal opposite to each other along the second direction, wherein the first terminal is located between the first dummy signal line and the plurality of data lines, and the second terminal is electrically connected to the gate driving chip.

15. The display panel according to claim 1, further comprising a cascaded gate driving circuit disposed in the non-display area, wherein:
a scan line of the plurality of scan lines includes a first terminal and a second terminal opposite to each other along the second direction, wherein the first terminal is located between the first dummy signal line and the plurality of data line, and the second terminal of the scan line is electrically connected to the cascaded gate driving circuit.

16. The display panel according to claim 15, wherein:
an output terminal of the cascaded gate driving circuit is electrically connected to the second end of the scan line through a connection hole; and
the second terminal is located between the first dummy signal line and the plurality of data lines.

17. The display panel according to claim 15, wherein:
the cascaded gate driving circuit is disposed in the non-display area on a same side of the display area along the second direction; or
the cascaded gate driving circuit is disposed in the non-display area on two opposite sides of the display area along the second direction, wherein odd-numbered scan lines of the plurality of scan lines are electrically connected to the cascaded gate driving circuit located on a same side of the display area, and even-numbered scan lines of the plurality of scan lines are electrically connected to the cascaded gate driving circuit located on the other side of the display area.

18. The display panel according to claim 1, wherein:
the non-display area includes a first non-display area located on at least one side of the display area along the second direction;
along a direction perpendicular to a plane where the substrate is located, a first insulating layer is disposed between a film layer where the plurality of scan lines is located and a film layer where the at least one dummy signal line is located; and
in the first non-display area, the first insulating layer has a thickness of S1, and in the display area, the first insulating layer has a thickness of S2, wherein S1≥S2.

19. The display panel according to claim 18, wherein:
the film layer where the at least one dummy signal line is located has a thickness of S0, wherein S0≥S1-S2.

20. A display device, comprising a display panel including a display area and a non-display area surrounding the display area, wherein the display panel includes:
a substrate;
a plurality of scan lines and a plurality of data lines disposed over the substrate, wherein the plurality of data lines is disposed in the display area, the plurality of data lines extends along a first direction and is arranged along a second direction, and the plurality of scan lines extends along the second direction and is arranged along the first direction, wherein the first direction and the second direction intersect; and
at least one dummy signal line disposed in the non-display area, wherein the at least one dummy signal line is parallel to the plurality of data lines, the at least one dummy signal line includes a first dummy signal line that is closest to an outer edge of the non-display area among the at least one dummy signal line, and along the second direction, one end of at least one scan line of the plurality of scan lines is located between the first dummy signal line and the plurality of data lines.
